(19) United States
(12) Patent Application Publication
(10) Pub. No.: US 2006/0228892 A1
(43) Pub. Date: Oct. 12, 2006

(54) Anti-reflective surface

(76) Inventors: Dennis M. Lazaroff, Corvallis, OR (US); Arthur R. Piehl, Corvallis, OR (US); Bhavin Shah, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/101,323

(22) Filed: Apr. 6, 2005

(51) Int. Cl. H01L 21/465; H01L 33/00

(52) U.S. Cl. 438/694; 257/72; 257/291; 438/712

(57) ABSTRACT

A discontinuous layer is formed on a transparent substrate of a semiconductor material. Portions of the transparent substrate are exposed at discontinuities in the discontinuous layer. The discontinuous layer and the exposed portions of the transparent substrate are etched at least until the discontinuous layer is completely removed, thereby forming peaks and valleys in the substrate.

### BACKGROUND

Light reflections off of surfaces, such as glass surfaces, can often degrade performance of a device. For example, reflections off of projection screens or micro displays of projectors act to degrade performance, e.g., the contrast ratio, of these devices. Anti-reflective coatings are often disposed on glass surfaces to reduce reflections. However, many common anti-reflective coatings, such as magnesium fluoride (MgF₂), tantalum pentoxide (Ta₂O₅), etc., are difficult pattern, making it difficult to integrate them into micro-displays, for example.

### DESCRIPTION OF THE DRAWINGS

FIGS. 1 and 2 are cross-sectional views during various stages of an embodiment of forming an anti-reflective surface, according to an embodiment of the present disclosure.

FIG. 3 is an embodiment of a micro-display, according to another embodiment of the present disclosure.

### DETAILED DESCRIPTION

In the following detailed description of the present embodiments, reference is made to the accompanying drawings that form a part hereof, and in which is shown by way of illustration specific embodiments that may be practiced. These embodiments are described in sufficient detail to enable those skilled in the art to practice disclosed subject matter, and it is to be understood that other embodiments may be utilized and that process, electrical or mechanical changes may be made without departing from the scope of the claimed subject matter. The following detailed description is, therefore, not to be taken in a limiting sense, and the scope of the claimed subject matter is defined only by the appended claims and equivalents thereof.

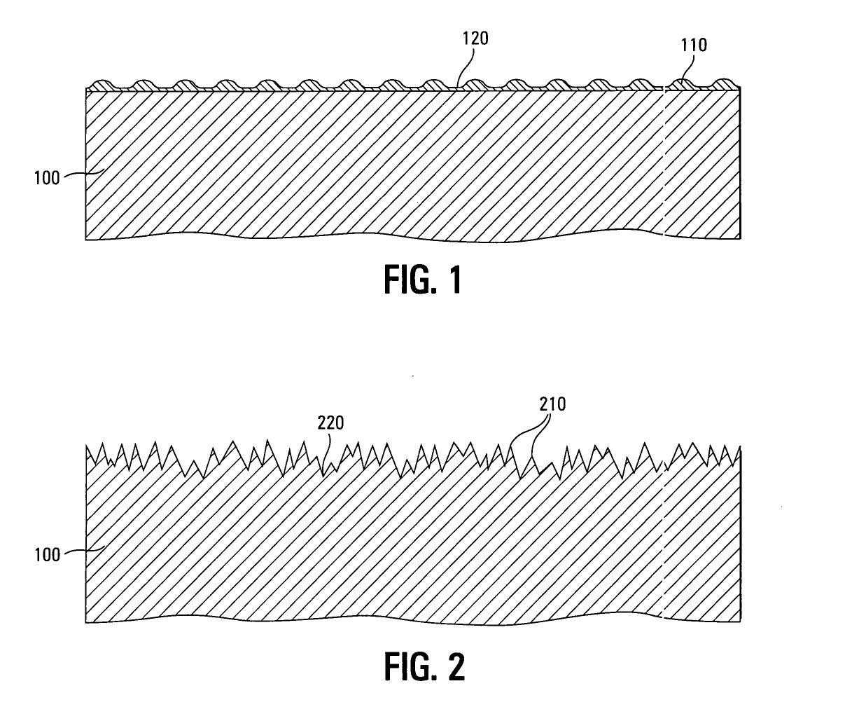

FIGS. 1 and 2 are cross-sectional views during various stages of forming an anti-reflective surface, according to an embodiment. The anti-reflective surface is formed in a surface of a substrate 100, such as a semiconductor substrate, e.g., of TEOS (tetraethylorthosilicate) oxide, silicon oxide (or glass), etc. For one embodiment, substrate 100 is transparent and may form a lens, part of a micro-display of a projector, part of a projection screen, such as a computer monitor screen, television screen, or the like, etc. The surface of transparent substrate 100 is coated with a thin, discontinuous metal layer 110, such as gold, aluminum, etc. For one embodiment, the metal layer 110 is formed thin enough, e.g., about 300 to about 400 angstroms, using a physical sputtering process, for example, such that regions of the metal layer 110 have holes 120 (or discontinuities) that expose the underlying substrate 100. Metal layer 110 acts as a hard-mask for a subsequent etch process.

For one embodiment, etching is accomplished using a reactive-ion process with fluorinated gasses. A reactive-ion etch process typically etches by as much as 15 times faster than a straight argon sputter etch. The etch process removes the material of substrate 100 faster than the metal layer 110, e.g., up to about 12 times faster. The etch continues until at least all of the metal layer 110 is removed, leaving spires (or peaks) 210 on substrate 100 corresponding to portions of substrate 100 covered by metal layer 110 and valleys 220 corresponding to portions of substrate 100 not covered by metal layer 110, as shown in FIG. 2, where peaks 210 and valleys 220 constitute an anti-reflective surface. For one embodiment, valleys 220 are about 4000 to about 5000 angstroms below the original exposed surface of substrate 100. Because the holes 120 form randomly during the physical sputtering process, the spires 210 have a corresponding random pattern. Note that spires 210 are pointed and have uneven heights, for some embodiments.

Note that the depths of valleys 220 are enabled by the reactive-ion etch and the thicknesses that can be realized using a metal layer 110, such as of gold. For example a metal layer 110 of gold can be thicker because gold does not stick well to oxide and tends to “bead up” when heated. Deeper valleys enhance anti-reflective properties because it is desirable to have valleys the spires about as deep as the wavelengths of light you are encountering, e.g., about 2000 to about 7000 angstroms.

The anti-reflective properties of the anti-reflective surface are achieved because the incoming light gets multiply reflected from one spire to another, resulting in absorption and/or interference that acts to reduce the reflection.

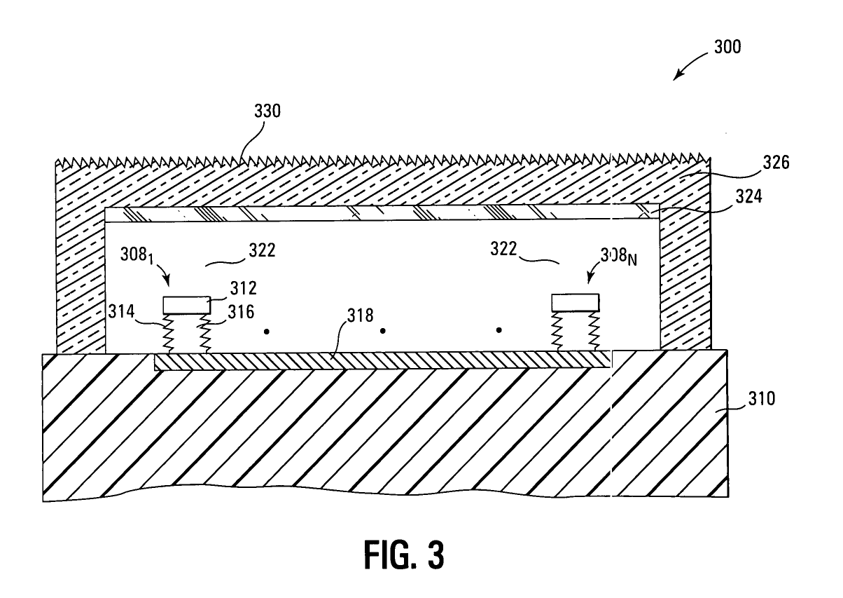

FIG. 3 is a cross-sectional view illustrating a micro-display 300, e.g., as a portion of a digital projector, according to an embodiment of the invention. For one embodiment, micro-display 300 functions as a light modulator of the digital projector. Micro-display 300 includes an array of pixels 308 formed on a first semiconductor substrate 310, e.g., of silicon or the like. For one embodiment, each pixel 308 is adapted to turn light received at the micro display on and off for respectively producing an active state (or displaying the light) and producing an inactive (or a “black”) state. For another embodiment, each pixel 308 is a MEMS device, such as a micro-mirror, liquid crystal on silicon (LcoS) device, interference-based modulator, etc. Specifically, for another embodiment, the MEMS device includes a micro-mirror 312 supported by flexures 314 so that a gap 316 separates the micro-mirror 312 from an electrode 318. A gap 322 separates micro-mirror 312 from a partially reflective layer 324, e.g., a tantalum aluminum (TaAl) layer, formed underlying a transparent substrate 326, e.g., of TEOS (tetraethylorthosilicate) oxide, silicon oxide (or glass), etc.

For one embodiment, transparent substrate 326 acts to reinforce and protect partially reflective layer 324. For another embodiment, an anti-reflective surface 330 is formed in a surface of transparent substrate 326, as described above, opposite a surface of transparent substrate 326 on which partially reflective layer 324 is formed. Anti-reflective surface 330 acts to reduce reflections of light received at micro-display 300. For other embodiments, anti-reflective surface 330 may be formed directly on the pixel surface if the pixel is made of an oxide layer with the partial reflector being on the underside of the pixel.

### CONCLUSION

Although specific embodiments have been illustrated and described herein it is manifestly intended that the scope of the claimed subject matter be limited only by the following claims and equivalents thereof.

What is claimed is:

1. A method of forming an anti-reflective surface, comprising:
forming a discontinuous layer on a transparent substrate of a semiconductor material, wherein portions of the transparent substrate are exposed at discontinuities in the discontinuous layer; and
etching the discontinuous layer and the exposed portions of the transparent substrate at least until the discontinuous layer is completely removed, thereby forming peaks and valleys in the substrate.

2. The method of claim 1, wherein the valleys are about 4000 to about 5000 angstroms deep.

3. The method of claim 1, wherein the discontinuous layer is a discontinuous metal layer.

4. The method of claim 3, wherein the metal layer is of gold.

5. The method of claim 1, wherein the discontinuous layer is formed using a physical sputtering process.

6. The method of claim 1, wherein etching comprises using a reactive-ion process with fluorinated gasses.

7. The method of claim 1, wherein the discontinuous layer is about 300 to about 400 angstroms thick.

8. The method of claim 1, wherein the semiconductor material is tetraethylorthosilicate oxide or silicon oxide.

9. The method of claim 1, wherein the discontinuous layer and the transparent substrate have different etch rates.

10. The method of claim 1, wherein the valleys in the substrate correspond to the exposed portions of the substrate and the peaks in the substrate correspond to portions of the substrate that were covered by the discontinuous layer.

11. A method of forming an anti-reflective surface, comprising:
forming a discontinuous layer of gold on a substrate, wherein portions of the transparent substrate are exposed at discontinuities in the discontinuous layer and other portions of the substrate are covered by the discontinuous layer; and
etching the discontinuous layer and the exposed portions of the substrate using a reactive-ion process with fluorinated gasses at least until the discontinuous layer is completely removed, thereby forming valleys in the substrate corresponding to the exposed portions of the substrate and peaks in the substrate corresponding to the portions of the substrate that were covered by the discontinuous layer.

12. The method of claim 11, wherein the valleys are about 4000 to about 5000 angstroms deep.

13. The method of claim 11, wherein the discontinuous layer is formed using a physical sputtering process.

14. The method of claim 11, wherein the discontinuous layer is about 300 to about 400 angstroms thick.

15. The method of claim 11, wherein the substrate is of tetraethylorthosilicate oxide or silicon oxide.

16. The method of claim 11, wherein the discontinuous layer and the substrate have different etch rates.

17. A method of forming a micro-display, comprising:
forming an array of pixels overlying a first semiconductor substrate; and
forming a transparent second semiconductor substrate overlying the array of pixels;
wherein forming the transparent second semiconductor substrate further comprises
forming an anti-reflective surface comprising:
forming a discontinuous layer on the transparent second semiconductor substrate, wherein portions of the transparent second semiconductor substrate are exposed-at discontinuities in the discontinuous layer; and
etching the discontinuous layer and the exposed portions of the transparent second semiconductor substrate at least until the discontinuous layer is completely removed, thereby forming peaks and valleys in the transparent second semiconductor substrate.

18. The method of claim 17, wherein the valleys are about 4000 to about 5000 angstroms deep.

19. The method of claim 17, wherein the discontinuous layer is a discontinuous metal layer.

20. The method of claim 19, wherein the metal layer is of gold.

21. The method of claim 17, wherein the discontinuous layer is formed using a physical sputtering process.

22. The method of claim 17, wherein etching comprises using a reactive-ion process with fluorinated gasses.

23. The method of claim 17, wherein the discontinuous layer is about 300 to about 400 angstroms thick.

24. The method of claim 17, wherein the transparent second semiconductor substrate is a tetraethylorthosilicate oxide or silicon oxide.

25. The method of claim 17, wherein the discontinuous layer and the transparent second semiconductor substrate have different etch rates.

26. The method of claim 17 further comprises forming a partially reflective layer on the transparent second semiconductor substrate opposite the anti-reflective surface.

27. The method of claim 26, wherein forming the array of pixels comprises forming a plurality of mirrors overlying the first semiconductor substrate.

28. The method of claim 27, wherein a gap separates the plurality of mirrors from the partially reflective layer.

29. A micro-display comprising:
a plurality of pixels; and
a transparent semiconductor substrate overlying the array of pixels, the transparent semiconductor substrate having an anti-reflective surface formed by a method comprising:
forming a discontinuous layer on the transparent semiconductor substrate, wherein portions of the transparent semiconductor substrate are exposed at the discontinuities in the discontinuous layer; and
etching the discontinuous layer and the exposed portions of the transparent semiconductor substrate at least until the discontinuous layer is completely removed, thereby forming peaks and valleys in the transparent semiconductor substrate.

30. The micro-display of claim 29, wherein, in the method, the valleys are about 4000 to about 5000 angstroms deep.

31. The micro-display of claim 29, wherein, in the method, the discontinuous layer is a discontinuous metal layer.

32. The micro-display of claim 31, wherein, in the method, the metal layer is of gold.

33. The micro-display of claim 29, wherein, in the method, the discontinuous layer is formed using a physical sputtering process.

34. The micro-display of claim 29, wherein, in the method, etching comprises using a reactive-ion process with fluorinated gasses.

35. The micro-display of claim 29, wherein, in the method, the discontinuous layer is about 300 to about 400 angstroms thick.

36. The method of claim 29, wherein the transparent semiconductor substrate is tetraethylorthosilicate oxide or silicon oxide.

37. The micro-display of claim 29, wherein, in the method, the discontinuous layer and the transparent semiconductor substrate have different etch rates.

38. The micro-display of claim 29 further comprises a partially reflective layer formed on the transparent semiconductor substrate opposite the anti-reflective surface.

39. The micro-display of claim 38, wherein the array of pixels comprises a plurality of mirrors overlying another semiconductor substrate.

40. The micro-display of claim 39, wherein a gap separates the plurality of mirrors from the partially reflective layer.
